(19) United States
(12) Patent Application Publication
(10) Pub. No.: US 2025/0075365 A1
(43) Pub. Date: Mar. 6, 2025

(54) WATER-COOLING JACKET DEVICE AND SINGLE-CRYSTAL FURNACE

(71) Applicant: XI’AN ESWIN MATERIAL TECHNOLOGY CO., LTD., Xi'an (CN)

(72) Inventor: Wenwu YANG, Xi'an (CN)

(21) Appl. No.: 18/951,547

(22) Filed: Nov. 18, 2024

Related U.S. Application Data
(63) Continuation of application No. PCT/CN2022/122979, filed on Sep. 30, 2022.

(30) Foreign Application Priority Data
May 18, 2022 (CN) 202210544317.6

(51) Int. Cl. C30B 15/00; C30B 29/06

(52) U.S. Cl. CPC C30B 15/00; C30B 29/06

(57) ABSTRACT

The present application discloses a water-cooling jacket device and a single-crystal furnace. The water-cooling jacket device includes a cylindrical body, and an adjustment sleeve provided at a bottom of the cylindrical body and in communication with an inside of the cylindrical body. The adjustment sleeve includes a first end connected with the cylindrical body and a second end opposite to the first end; and a cross-sectional area of the adjustment sleeve in a radial direction of the cylindrical body gradually decreases from the first end to the second end.

### CROSS-REFERENCE TO RELATED APPLICATION

This application is Bypass Continuation Application of PCT Application No. PCT/CN2022/122979 filed on Sep. 30, 2022, which claims the priority of Chinese Application No. 202210544317.6, filed on May 18, 2022, the disclosures of which are incorporated in their entirety by reference herein.

### TECHNICAL FIELD

The present disclosure relates to the field of single crystal silicon product manufacturing technologies, and in particular to a water-cooling jacket device and a single-crystal furnace.

### BACKGROUND

With continuous improvement of advanced semiconductor processes, quality requirements for semiconductor wafers are getting higher and higher. As for the quality of the wafers, the crystal pulling process has a great impact on the core quality of the wafers, for example, oxygen content, bulk micro defects (BMD), stacking faults, crystal originated particles (COPs), flow pattern defects (FPD), laser scattering tomography defects (LSTDs) and other qualities are all closely related to the crystal pulling process.

The thermal history of a crystal ingot during its growth process greatly affects the overall quality of the crystal ingot, and the thermal history is mainly affected by longitudinal and axial temperature gradients of the crystal ingot. Structural components of a crystal pulling furnace have a great influence on the temperature gradients. One of the most important components is a water-cooling jacket, which changes longitudinal and transverse temperature gradients of the crystal ingot to a great extent, increases a cooling rate of the crystal ingot, thereby affecting a pulling rate of the crystal ingot.

In the related art, the water-cooling jacket is cylindrical, which greatly limits an axial and longitudinal temperature regulation of the crystal ingot by the water-cooling jacket, and thus crystal defects of the crystal ingot cannot be well controlled. For example, the limited regulation ability leads to inability to conduct heat from a center of the crystal ingot well, resulting in excessive internal stress accumulation, which in turn leads to misalignment. This greatly affects the quality of the crystal ingot. Especially for epitaxial products, stacking faults will cause uneven deposition and even deposition failure for epitaxial products during epitaxial deposition.

### SUMMARY

In order to solve the foregoing technical problems, the present application provides a water-cooling jacket device and a single-crystal furnace, which can solve the problem of limited temperature adjustment in the axial and longitudinal directions of the crystal ingot.

In order to achieve the above purpose, the technical solutions provided in the embodiments of the present disclosure are as follows. A water-cooling jacket device includes: a cylindrical body, and an adjustment sleeve provided at a bottom of the cylindrical body and in communication with an inside of the cylindrical body; wherein the adjustment sleeve includes a first end connected with the cylindrical body and a second end opposite to the first end; and a cross-sectional area of the adjustment sleeve in a radial direction of the cylindrical body gradually decreases from the first end to the second end.

Optionally, an inner surface of the adjustment sleeve is a curved surface.

Optionally, a cross-section shape of the adjustment sleeve in an axial direction of the cylindrical body is a parabolic shape.

Optionally, in an axial direction of the cylindrical body, the adjustment sleeve includes a first part close to the cylindrical body and a second part adjacent to the first part; an outer surface of the second part is concave to form a recess portion.

Optionally, an inner surface of the adjustment sleeve is provided with a heat absorption layer.

Optionally, the heat absorption layer includes a first layer close to the adjustment sleeve and a second layer away from the adjustment sleeve; and the first layer is a transition layer formed by a chemical reaction between graphite material and an inner wall of the adjustment sleeve.

Optionally, the first layer is a composite transition coating of C and SiC; and the second layer is a SiC coating.

Optionally, a thickness of the heat absorption layer is 130±15 microns.

Optionally, an outer surface of the adjustment sleeve is provided with a heat insulation layer.

Optionally, the heat insulation layer includes a third layer close to the adjustment sleeve and a fourth layer away from the adjustment sleeve; the third layer is a transition layer formed by a chemical reaction between graphite material and an outer wall of the adjustment sleeve.

Optionally, the third layer is a composite transition coating of C and SiC; and the fourth layer is a SiC coating.

Optionally, a thickness of the thermal insulation layer is 160±15 microns.

Optionally, the cylindrical body includes an inner cylinder and an outer cylinder located outside the inner cylinder; a bottom of the outer cylinder includes a first region for carrying the inner cylinder 2 and a second region adjacent to the first region; the first region is arranged close to a side wall of the outer tube; a top of the adjustment sleeve is provided with a flange; and the flange is connected to the second region.

One embodiment of the present application further provides a single-crystal furnace, including the above water-cooling jacket device.

The beneficial effects of the present application are: through the arrangement of the adjustment sleeve, heat underneath the cylindrical body is blocked from being transmitted to an internal space of the water-cooling jacket, thereby effectively blocking heat dissipation from bottom to top. When inert gas flow is blown from above of a crystal pulling furnace and flows through the adjustment sleeve, the flow rate increases, thereby ensuring sufficient contact between the inert gas flow and the crystal ingot and improving the cooling rate of the crystal ingot. This well adjusts longitudinal and radial temperature gradients of the crystal ingot, controls reaction rate of defects in the crystal ingot, adjusts defect distribution and draws different types of crystal ingots.

### BRIEF DESCRIPTION OF THE DRAWINGS

FIG. 1 shows a schematic diagram of a water-cooling jacket device according to an embodiment of the present application;

FIG. 2 shows a schematic diagram of an adjustment sleeve according to an embodiment of the present application;

FIG. 3 shows a schematic diagram of an inner cylinder according to an embodiment of the present application;

FIG. 4 shows a schematic diagram of an outer cylinder according to an embodiment of the present application;

FIG. 5 shows a first schematic diagram of a lifting rod according to an embodiment of the present application;

FIG. 6 shows a second schematic diagram of a lifting rod according to an embodiment of the present application; and

FIG. 7 shows a schematic diagram of a connection part according to an embodiment of the present application.

### DETAILED DESCRIPTION

In order to make the objects, the technical solutions and the advantages of the present disclosure more apparent, the technical solutions of embodiments of the present application will be described hereinafter in a clear and complete manner in conjunction with the drawings and embodiments. Obviously, the following embodiments are merely a part of, rather than all of, the embodiments of the present application, and based on these embodiments, a person skilled in the art may obtain the other embodiments, which also fall within the scope of the present disclosure.

In the description of the present application, it is to be noted that orientation or positional relationship indicted by the terms “center”, “upper”, “lower”, “left”, “right”, “vertical”, “horizontal”, “inner”, “outer” and the like, are orientation or positional relationship shown in the drawings. They are only for the convenience of describing the present application and simplifying the description, and do not indicate or imply that referred devices or elements must have a specific orientation, be constructed and operate in a specific orientation, and therefore should not be understood as limiting the present application. In addition, the terms “first”, “second” and “third” are used for descriptive purposes only and are not to be construed as indicating or implying relative importance.

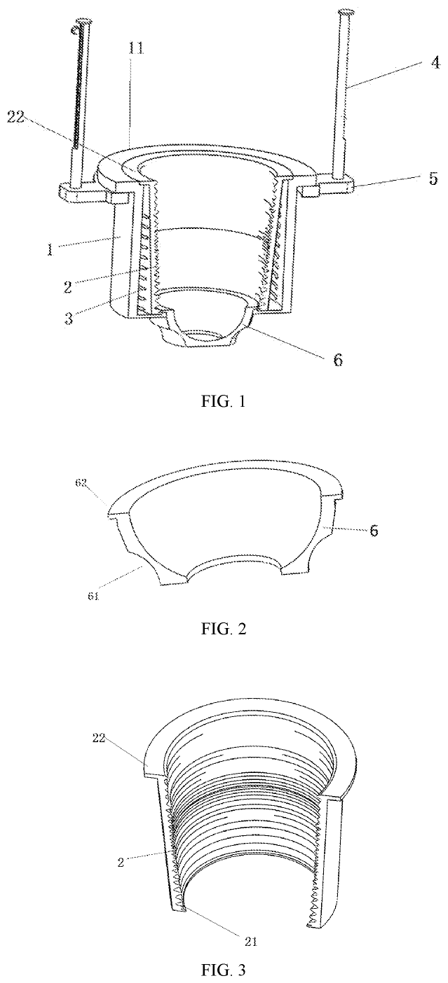

Referring to FIG. 1 and FIG. 2, this embodiment provides a water-cooling jacket device, which includes a cylindrical body. An adjustment sleeve 6 is provided at a bottom of the cylindrical body, and is communicated with an inside of the cylindrical body. The adjustment sleeve 6 includes a first end connected with the cylindrical body and a second end opposite to the first end. A cross-sectional area of the adjustment sleeve 6 in a radial direction of the cylindrical body gradually decreases from the first end to the second end.

Through the arrangement of the adjustment sleeve 6, heat underneath the cylindrical body is blocked from being transmitted to an internal space of the water-cooling jacket, thereby effectively blocking heat dissipation from bottom to top. Further, since the cross-sectional area of the adjustment sleeve 6 in the radial direction of the cylindrical body gradually decreases, when inert gas flow is blown from above of a crystal pulling furnace and flows through the adjustment sleeve, the flow rate increases, thereby ensuring sufficient contact between the inert gas flow and the crystal ingot and improving the cooling rate of the crystal ingot. This well adjusts longitudinal and radial temperature gradients of the crystal ingot, controls reaction rate of defects in the crystal ingot, adjusts defect distribution and draws different types of crystal ingots.

For example, an inner surface of the adjustment sleeve 6 is a curved surface.

For example, a cross-section shape of the adjustment sleeve 6 in an axial direction of the cylindrical body is a parabolic shape.

For example, in the axial direction of the cylindrical body, the adjustment sleeve 6 includes a first part close to the cylindrical body and a second part adjacent to the first part. An outer surface of the second part is concave to form a recess portion 61.

The water-cooling jacket is located above a crucible, and the presence of the recess portion 61 can directionally reflect heat from below to a graphite component or a silicon melt surface below the water-cooling jacket, thereby maintaining stability of the temperature field below.

For example, the inner surface of the adjustment sleeve 6 is provided with a heat absorption layer.

The heat absorption layer has a heat-absorbing effect. A bonding strength between the heat absorption layer and the adjustment sleeve 6 is high, which can effectively relieve thermal stress at an interface of the heat absorption layer (i.e., a connection surface between the heat absorption layer and the adjustment sleeve 6) and has stable thermodynamic properties. The adjustment sleeve 6 can take away the heat transmitted by the crystal ingot in real time, thereby greatly improving a cooling rate of the crystal ingot, increasing a pulling speed, and increasing a crystal pulling efficiency.

For example, the heat absorption layer includes a first layer close to the adjustment sleeve 6 and a second layer away from the adjustment sleeve. The first layer is a transition layer formed by a chemical reaction between the graphite material and an inner wall of the adjustment sleeve 6.

The adjustment sleeve is made of carbon fiber composite material, the first layer is a composite transition coating of C and SiC (with a thickness of 80±10 microns), and the second layer is a SiC coating (with a thickness of 50±5 microns). Such a coating structure (a combination of the above heat absorption layer and the adjustment sleeve) has characteristics of high bonding strength and high density. It can protect the body very well and extend its service life.

For example, the thickness of the heat absorption layer is 130±15 microns.

For example, an outer surface of the adjustment sleeve 6 is provided with a heat insulation layer.

The heat insulation layer has functions of reflecting and shielding heat, which can prevent external heat from being transmitted from the adjustment sleeve 6 to the inside of the water-cooling jacket, and maintain a constant temperature inside the water-cooling jacket.

For example, the heat insulation layer includes a third layer close to the adjustment sleeve 6 and a fourth layer away from the adjustment sleeve. The third layer is a transition layer formed by a chemical reaction between the graphite material and an outer wall of the adjustment sleeve 6.

The adjustment sleeve is made of carbon fiber composite material, the third layer is a composite transition coating of C and SiC (with a thickness of 80±10 microns), and the fourth layer is a SiC coating (with a thickness of 50±10 microns). Such a coating structure (a combination of the above heat insulation layer and the adjustment sleeve) has the characteristics of high bonding strength and high density. It can protect the body very well and extend its service life.

For example, the thickness of the thermal insulation layer is 160±15 microns.

For example, the cylindrical body includes an inner cylinder 2 and an outer cylinder 1 located outside the inner cylinder 2.

A bottom of the outer cylinder 1 includes a first region for carrying the inner cylinder and a second region adjacent to the first region. The first region is arranged close to a side wall of the outer tube 1. A top of the adjustment sleeve 6 is provided with a flange (third flange 62). The flange is connected to the second region.

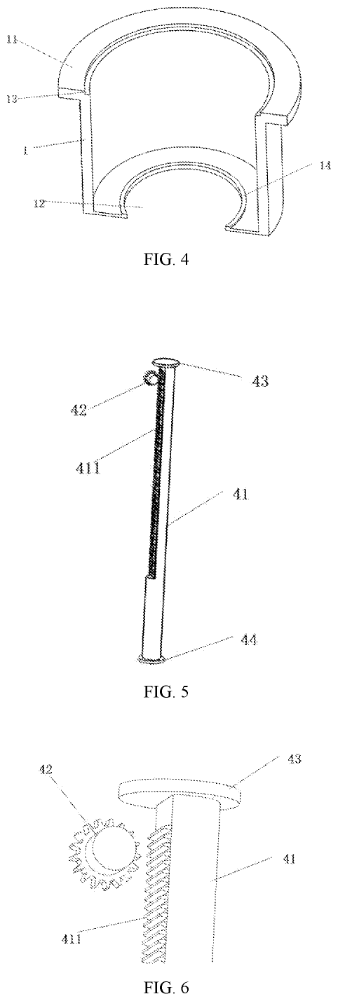

Referring to FIG. 1, FIG. 3 and FIG. 4, for example, the inner cylinder 2 has an inverted conical structure.

Compared with a single straight-cylinder structure, this embodiment adopts a double-layer structure of an inner cylinder and an outer cylinder. The outer cylinder adopts a straight-cylinder structure. The outer cylinder acts as a heat barrier. The inner cylinder adopts an inverted cone structure, which can form a longitudinal gradient water cooling effect. The temperature of the crystal ingot in the longitudinal direction (i.e. the axial direction of the crystal ingot) changes in a gradient (the lower end is hot and the upper end is cold, the end close to the silicon melt is the lower end, and the end away from the silicon melt is the upper end). The heat of the crystal ingot is mainly transmitted to surrounding objects with low temperature in form of radiation. The intensity of radiation heat transfer is inversely proportional to the cube of the distance, that is, the closer the distance, the stronger the radiation heat transfer, and the better the corresponding water cooling effect. The inner cylinder is in an inverted cone shape, and a distance between the inner wall of the inner cylinder and the crystal ingot in the radial direction of the crystal rod changes gradually along the longitudinal direction, thereby achieving gradient water cooling effects. That is, the longitudinal asymmetric effect is realized to achieve radial and axial gradient temperature changes, thereby greatly improving the axial and radial heat dissipation of the crystal ingot, reducing internal heat accumulation, changing the thermal history of the crystal ingot, reducing occurrence of misalignment and other crystal defects, and improving the quality of the crystal rod. An inclination angle of the inner wall of the inner cylinder can be adjusted according to requirements of the pulling process, which can greatly adjust the longitudinal (i.e., axial) and radial temperature gradients of the crystal ingot, control the reaction rate of defects in the crystal ingot, and adjust the defect distribution.

For example, an inner diameter of the top of the inner cylinder is 450 mm, and an inner diameter of the bottom of the inner cylinder is 390 mm, which is limited thereto.

The top of the inner cylinder is provided with a second flange 22. The top of the outer cylinder is provided with a first flange 11. A stepped groove 13 is provided on one side of the first flange 11 close to the inner cylinder. The second flange 22 is disposed in the stepped groove 13.

A first surface of the second flange 22 away from the bottom of the inner cylinder and a second surface of the first flange 11 away from the bottom of the inner cylinder are located on the same plane.

A first through hole is defined in the bottom of the inner cylinder. A second through hole 12 is defined in the bottom of the outer cylinder. An orthogonal projection of the center of the first through hole onto the bottom of the outer cylinder 1 coincides with the center of the second through hole 12.

For example, an annular protrusion 14 protrudes from an edge of the second through hole 12 toward the top of the outer cylinder 1. The annular protrusion 14 functions as a retaining wall to limit the position of the inner cylinder 2.

For example, along the axial direction of the inner cylinder 2, a toothed corrugated structure 21 is provided on the inner wall of the inner cylinder 2.

The presence of the toothed corrugated structure 21 can increase a surface area of the inner wall of the inner cylinder, that is, the heat absorption area of the water-cooling jacket is increased. Compared with a smooth surface, such a surface has a better heat absorption effect and has a good cooling effect of the crystal ingot.

The toothed corrugated structure 21 includes a plurality of annular teeth extending along a circumferential direction of the inner cylinder 2. The plurality of annular teeth are arranged along the axial direction of the inner cylinder 2. The cross-sectional shape of a single annular tooth can be triangle, trapezoid, arc, etc.

For example, in a direction from the top of the inner cylinder 2 to the bottom of the inner cylinder 2, a thickness of the toothed corrugated structure 21 in the radial direction of the inner cylinder 2 gradually increases.

For example, the inner side wall of the inner cylinder 2 is provided with a heat-absorbing coating.

The heat-absorbing coating is disposed on one side of the toothed corrugated structure 21 away from the outer cylinder 1. The shape of the heat-absorbing coating matches the shape of the toothed corrugated structure 21, that is, a connection surface between the heat-absorbing coating and the inner cylinder 2 and an inner surface opposite to the connection surface are both toothed corrugated structure.

The heat-absorbing coating has a heat-absorbing effect. A bonding strength between the heat-absorbing coating and the inner cylinder 2 is high, which can effectively relieve thermal stress at an interface of the heat-absorbing coating (i.e., a connection surface between the heat-absorbing coating and the inner cylinder 2) and has stable thermodynamic properties. The inner cylinder 2 can take away the heat transmitted by the crystal ingot in real time, thereby greatly improving a cooling rate of the crystal ingot, increasing a pulling speed, and increasing a crystal pulling efficiency.

For example, a thickness of the heat-absorbing coating in the radial direction of the inner cylinder 2 gradually increases from the top of the inner cylinder 2 to the bottom of the inner cylinder 2.

For example, the heat-absorbing coating is made of ceramic, which is not limited thereto.

For example, the thickness of the heat-absorbing coating is 200±25 microns.

For example, a heat insulation coating is provided on the outer wall of the inner cylinder 2 and/or the inner wall of the outer cylinder 1.

The heat insulation coating has the function of reflecting and shielding heat, and prevents external heat from being transmitted from the outer cylinder 1 to the inside of the water-cooling jacket (i.e., the inside of the inner cylinder 2), thereby maintaining a constant temperature inside the water-cooling jacket.

For example, the outer wall of the inner cylinder 2 is provided with the heat insulation coating. A thickness of the heat insulation coating in the radial direction of the inner tube 2 gradually increases from the top of the inner tube 2 to the bottom of the inner tube 2.

For example, the heat insulation coating is made of high-temperature-resistant and heat-insulating zirconia ceramics.

For example, a thickness of the heat insulation coating is 100±25 microns, which is not limited thereto.

For example, along the axial direction of the inner cylinder 2, a water-cooling pipe 3 is spirally distributed around the outer wall of the inner cylinder 2.

The water-cooling pipe 3 can be provided on the outer wall of the inner cylinder 2 or on the inner wall of the outer cylinder 1.

The specific structural form of the water-cooling pipe 3 is not limited to this. For example, the water-cooling pipe 3 can be in a serpentine shape and distributed on the outer wall of the inner cylinder 2. The water-cooling pipe 3 can be serpentine-shaped, including a plurality of straight pipes 3 extending along the axial direction of the inner cylinder 2 and a bent pipe 3 disposed between two adjacent straight pipes 3.

For example, a diameter of the water-cooling pipe 3 gradually increases in the direction from the top of the inner cylinder 2 to the bottom of the inner cylinder 2.

With the above solution, the water cooling effect of the water-cooling pipe 3 changes gradually along the axial direction of the inner cylinder 2, which is beneficial to adjustment of the gradient temperature in the radial direction and the axial direction.

For example, the diameter of the water-cooling pipe is 5 mm-10 mm, which is not limited thereto.

For example, a circumferential spacing of the water-cooling pipe in the direction from the top of the inner cylinder 2 to the bottom of the inner cylinder 2 is 48 mm.

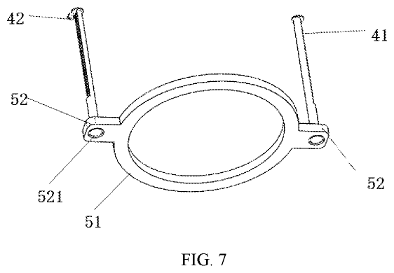

Referring to FIG. 1 and FIGS. 5-7, exemplarily, the water-cooling jacket device in this embodiment further includes a lifting structure for controlling the lifting of the cylindrical body.

The cylindrical body includes an inner cylinder 2 and an outer cylinder 1 located outside the inner cylinder 2.

The lifting structure includes two lifting parts 4 arranged oppositely on two sides of the cylindrical body. Each lifting part 4 includes a driving part and a transmission part. The transmission part is connected to the outer cylinder 1 through a connecting structure which allows the two lifting parts 4 to move asynchronously to drive the cylindrical body to tilt at a preset angle.

The presence of the lifting structure can control the lifting of the cylindrical body. The two lifting parts 4 are driven independently, so that the two lifting parts 4 can move asynchronously, so that the cylindrical body can be tilted within a preset angle range to form an asymmetric water cooling effect. The large gradient change can accelerate the transfer of heat from the crystal ingot to the water-cooling jacket, thereby improving the heat transfer efficiency, and accelerating the axial and radial heat dissipation of the crystal ingot. According to the needs of the pulling process, the longitudinal temperature gradient and radial temperature gradient of the crystal ingot can be adjusted to a large extent, thereby controlling the reaction rate of defects in the crystal rod and adjusting the defect distribution. Then, a good cooling rate is provided, so that crystal ingots with different defect types (such as stacking fault-free crystal ingots, BMD crystal ingots) can be pulled.

Crystal ingots with different process parameter requirements need to be matched with different water cooling effects. The asynchronously moving water-cooling jacket device can be adjusted accordingly to obtain appropriate cooling effects according to needs.

The purpose of the asynchronous movement is to create a radial asymmetry effect and improve the water cooling effect. The function of the lifting mechanism is that: when pulling epitaxial crystal ingots, a large pulling speed is required, then the water-cooling jacket moves toward the liquid surface to increase the cooling effect, thereby increasing the pulling speed; when pulling defect-free polished crystal ingots, the water-cooling jacket can be moved upward to inhibit the formation of COP; when pulling BMD crystal ingots, the nucleation and growth of BMD needs to be promoted, then through adjustment via movement of the water-cooling jacket, BMD can be nucleated at a low temperature of 650° C.-700° C.; meanwhile, for the high temperature area, the asynchronous movement adjustment can be used to expand the crystal ingot range within the temperature range of 750° C.-1100° C. In this way, the high-temperature nucleation of BMD is promoted.

It is to be noted that under action of the lifting structure, cooperation of the two opposite lifting parts 4 can enable the cylindrical body to tilt and lift. That is, after the two lifting parts 4 are asynchronously moved to tilt the cylindrical body to a preset angle, the two lifting parts 4 are controlled to move synchronously to control the cylindrical body to move up and down in a tilted state.

It is to be noted that the number of the lifting parts 4 included in the lifting structure is not limited. Two lifting parts 4 are disposed on opposite sides of the cylindrical body, and the two opposite lifting parts 4 are one group. The lifting structure may include multiple groups of lifting parts 4. Each group of lifting parts 4 can enable the cylindrical body to be tilted in one direction, so that multiple groups of lifting parts 4 can be provided according to actual needs, thereby flexibly controlling the tilt direction of the cylindrical body, and better controlling the water cooling effect.

It is to be noted that the cooperation of the two opposite lifting parts 4 can enable the water-cooling jacket body to tilt and lift. The tilt angle can be set according to actual needs, for example, it can be 0 degrees to 17 degrees, which is not limited thereto.

For example, the transmission part include:
a lifting rod 41 which extends along the axial direction of the outer cylinder 1, and includes a gear-rack structure 411 provided on an outer surface of the lifting rod 41;
a transmission gear 42 which is engaged with the gear-rack structure 411, to be drivingly connected to the lifting rod 41.

In this embodiment, the transmission gear 42 is engaged with the lifting rod 41. When the transmission gear 42 rotates, under transmission action of the lifting rod 41, the cylindrical body is lifted up or down.

For example, the driving part of each lifting part 4 may be a driving motor.

For example, the outer surface of one lifting rod 41 has a first portion away from the other lifting rod 41. The first portion is concave to form a connecting surface, and the connecting surface is provided with the gear-rack structure 411.

The connecting surface is a plane parallel to the axial direction of the outer cylinder 1. The presence of the gear-rack structure 411 on the connecting surface facilitates engagement between the gear-rack structure 411 and the transmission gear 42.

For example, the gear-rack structure 411 includes a plurality of parallel gear-racks protruding from the connecting surface. The plurality of gear-racks are arranged side by side along the axial direction of the outer cylinder 1. A tooth groove is formed between two adjacent gear-racks.

An extension direction of the gear-rack is perpendicular to the axial direction of the outer cylinder 1. An axial direction of the transmission gear 42 is parallel to the extension direction of the gear-rack. The teeth of the transmission gear 42 correspond to the tooth grooves, so that rotation of the transmission gear 42 drives the lifting rod 41 to perform lifting movements, thereby driving the cylindrical body to move up and down, thereby driving the cylindrical body to move up and down.

For example, the gear-rack is a threaded rack, and the threaded rack has the characteristics of high precision and large load.

For example, a limiter 43 is provided at one end of the lifting rod 41 away from the outer cylinder 1.

The presence of the limiter 43 prevents the transmission gear 42 from being separated from the lifting rod 41. The limiter 43 can be a circular structure. An area of the limiter 43 in the radial direction of the lifting rod 41 is larger than a cross-sectional area of an end surface of the lifting rod 41.

The limiter 43 and the lifting rod 41 may be an integral structure connected through welding or other processes, or may be formed simultaneously when the connecting surface is formed. The first portion may be at a middle of the lifting rod 41. A groove is formed in the first portion, and a bottom surface of the groove is the connecting surface. Then, in the axial direction of the lifting rod 41, a first side wall of the groove away from the outer cylinder 1 forms the limiter 43, and a second side wall of the groove opposite to the first side wall forms a limit retaining wall for limiting the movement stroke of the transmission gear 42.

For example, in the axial direction of the outer cylinder 1, a length of the first portion is less than a length of the lifting rod 41, and the first portion is located at an end of the lifting rod 41 away from the outer cylinder 1.

For example, in the axial direction of the outer cylinder 1, the length of the first portion is greater than a half of the length of the lifting rod 41.

For example, the connecting part 5 includes a snap ring 51 that is sleeved on the outside of the outer cylinder 1. Two protrusions 52 are formed on opposite sides of the snap ring 51. Each of the protrusions 52 is provided with a connection through hole 521 for connecting with the corresponding lifting rod 41.

For example, a connecting ring 44 is provided at one end of the lifting rod 41 close to the outer cylinder 1. The connecting ring 44 is threadedly connected to the lifting rod 41. The lifting rod 41 is loosely engaged with the protrusion 52 with a gap therebetween, so that the water-cooling jacket can be tilted when the two lifting rods 41 move asynchronously.

For example, a first flange 11 is provided on the top of the outer cylinder 1. The snap ring 51 is provided on a side of the first flange 11 close to the bottom of the outer cylinder 1.

The snap ring 51 can be bonded to the first flange 11 through an adhesive layer to enhance the connection strength between the connecting part 5 and the outer cylinder 1.

One embodiment of the present application further provides a single-crystal furnace, including the water-cooling jacket device, a furnace body, and a crucible located in the furnace body. The cylindrical body is arranged above the crucible under the lifting effect of the lifting structure.

It is to be understood that the above embodiments are only exemplary embodiments adopted to illustrate the principles of the present application, but the present application is not limited thereto. For those of ordinary skill in the art, various modifications and improvements can be made without departing from the spirit and essence of the present application, and these modifications and improvements are also regarded as falling in the protection scope of the present application.

What is claimed is:

1. A water-cooling jacket device, comprising:
a cylindrical body, and an adjustment sleeve provided at a bottom of the cylindrical body and in communication with an inside of the cylindrical body, wherein the adjustment sleeve includes a first end connected with the cylindrical body and a second end opposite to the first end; and
wherein a cross-sectional area of the adjustment sleeve in a radial direction of the cylindrical body gradually decreases from the first end to the second end.

2. The water-cooling jacket device according to claim 1, wherein an inner surface of the adjustment sleeve is a curved surface.

3. The water-cooling jacket device according to claim 2, wherein a cross-section shape of the adjustment sleeve in an axial direction of the cylindrical body is a parabolic shape.

4. The water-cooling jacket device according to claim 1, wherein in an axial direction of the cylindrical body, the adjustment sleeve includes a first part close to the cylindrical body and a second part adjacent to the first part; an outer surface of the second part is concave to form a recess portion.

5. The water-cooling jacket device according to claim 1, wherein an inner surface of the adjustment sleeve is provided with a heat absorption layer.

6. The water-cooling jacket device according to claim 5, wherein:
the heat absorption layer includes a first layer close to the adjustment sleeve and a second layer away from the adjustment sleeve; and
the first layer is a transition layer formed by a chemical reaction between graphite material and an inner wall of the adjustment sleeve.

7. The water-cooling jacket device according to claim 6, wherein the first layer is a composite transition coating of C and SiC; and the second layer is a SiC coating.

8. The water-cooling jacket device according to claim 5, wherein a thickness of the heat absorption layer is 130±15 microns.

9. The water-cooling jacket device according to claim 1, wherein an outer surface of the adjustment sleeve is provided with a heat insulation layer.

10. The water-cooling jacket device according to claim 9, wherein:
the heat insulation layer includes a third layer close to the adjustment sleeve and a fourth layer away from the adjustment sleeve; and
the third layer is a transition layer formed by a chemical reaction between graphite material and an outer wall of the adjustment sleeve.

11. The water-cooling jacket device according to claim 10, wherein:
the third layer is a composite transition coating of C and SiC; and
the fourth layer is a SiC coating.

12. The water-cooling jacket device according to claim 9, wherein a thickness of the heat insulation layer is 160±15 microns.

13. The water-cooling jacket device according to claim 1, wherein:
the cylindrical body includes an inner cylinder and an outer cylinder located outside the inner cylinder;
a bottom of the outer cylinder includes a first region for carrying the inner cylinder and a second region adjacent to the first region;
the first region is arranged close to a side wall of the outer cylinder; and
a top of the adjustment sleeve is provided with a flange; and the flange is connected to the second region.

14. The water-cooling jacket device according to claim 13, wherein the inner cylinder has an inverted conical structure.

15. The water-cooling jacket device according to claim 14, wherein along an axial direction of the inner cylinder, a toothed corrugated structure is provided on an inner wall of the inner cylinder.

16. The water-cooling jacket device according to claim 15, wherein in a direction from a top of the inner cylinder to a bottom of the inner cylinder, a thickness of the toothed corrugated structure in a radial direction of the inner cylinder gradually increases.

17. A single-crystal furnace, comprising:
a water-cooling jacket device including a cylindrical body, and an adjustment sleeve provided at a bottom of the cylindrical body and in communication with an inside of the cylindrical body;
wherein the adjustment sleeve includes a first end connected with the cylindrical body and a second end opposite to the first end; and
wherein a cross-sectional area of the adjustment sleeve in a radial direction of the cylindrical body gradually decreases from the first end to the second end.

18. The single-crystal furnace according to claim 17, wherein:
the single-crystal furnace further includes a furnace body, and
a crucible is located in the furnace body; and
the cylindrical body is arranged above the crucible.
